(19) United States
(12) Patent Application Publication
(10) Pub. No.: US 2026/0064009 A1
(43) Pub. Date: Mar. 5, 2026

(54) METHOD FOR TRAINING OPC MODELING PARAMETER

(71) Applicant: Shanghai Huali Integrated Circuit Corporation, Shanghai (CN)

(72) Inventor: Shunkui KE, Shanghai (CN)

(73) Assignee: Shanghai Huali Integrated Circuit Corporation, Shanghai (CN)

(21) Appl. No.: 19/184,246

(22) Filed: Apr. 21, 2025

(30) Foreign Application Priority Data
Aug. 30, 2024 (CN) 202411215465.9

(51) Int. Cl. G03F 7/00; G06N 3/08

(52) U.S. Cl. CPC G03F 7/70441; G03F 7/705; G03F 7/70625; G03F 7/706841; G06N 3/08

(57) ABSTRACT

The present disclosure provides a method for training an OPC modeling parameter, including: step 1: designing a plurality of OPC patterns according to a design requirement for a lithography process layer layout; selecting at least one model parameter as a selected model parameter requiring training, and setting a plurality of different values for the selected model parameter; and collecting wafer pattern data formed by performing a lithography process on each OPC pattern; step 2: generating a sample unit and a sample set based on the collected data; step 3: inputting data of the sample set into a neural network for training; and step 4: performing OPC modeling using the trained neural network, where during the OPC modeling, an optimal value of the selected model parameter is obtained using the trained neural network, and the optimal value of the selected model parameter is used to perform the OPC modeling.

### CROSS-REFERENCES TO RELATED APPLICATIONS

This application claims priority to Chinese patent application No. CN202411215465.9, filed on Aug. 30, 2024, the disclosure of which is incorporated herein by reference in its entirety.

### TECHNICAL FIELD

The present disclosure relates to a method for manufacturing a semiconductor integrated circuit, and in particular to a method for training an optical proximity correction (OPC) modeling parameter.

### BACKGROUND

With the continuous development of wafer foundry process technology, a critical dimension at a logical device node is close to or even less than the wavelength of light waves used in the lithography process. According to the principle of diffraction and interference of light waves, the diffraction occurs when the light waves pass through a mask, and the interference occurs at different positions of the mask. Therefore, an actual light intensity distribution projected onto a wafer is a result of superposition of the diffraction and interference light waves, which is not the same as a mask pattern. Such a phenomenon of a deviation between a lithography pattern and the mask pattern due to the diffraction and interference of light waves is referred to as optical proximity effect (OPE). In the lithography process, the optical proximity effect is inevitable. According to an existing method, an OPC technology is used to minimize deformation and deviation of the mask pattern projected onto a wafer pattern, so that an exposed pattern satisfies a design requirement.

Currently, OPC technology development for an advanced process node less than the wavelength of 193 nm is mainly based on an OPC model method, that is, an OPC model is used to simulate a lithography machine. The precision of the OPC model plays an extremely important role in the overall OPC correction effect. A reasonable setting of a model parameter is crucial to the established OPC model, for example, a large optical diameter (OD) may lead to an exponential increase of computation time, and a small OD may affect the precision of the OPC model although it lowers the computation precision.

### BRIEF SUMMARY

According to some embodiments in this application, a method for for training an OPC modeling parameter is disclosed in the following steps:
step 1: collecting OPC modeling data, including:
designing a plurality of OPC patterns according to a design requirement for a lithography process layer layout;
selecting at least one model parameter as a selected model parameter requiring training, and setting a plurality of different values for each selected model parameter; and collecting wafer pattern data formed by performing a lithography process on each OPC pattern based on different values of the selected model parameter;
step 2: generating a sample unit and a sample set based on the collected data;
step 3: inputting data of the sample set into a neural network for training; and
step 4: performing OPC modeling using the trained neural network, where during the OPC modeling, an optimal value of the selected model parameter is obtained using the trained neural network, and the optimal value of the selected model parameter is used to perform the OPC modeling.

In some cases, in step 1, the designed OPC patterns are required to cover all circuit layout pattern requirements in the lithography process layer layout.

In some cases, the lithography process layer layout includes a hole layer layout.

In some cases, the OPC patterns corresponding to the hole layer layout include:
a grating formed by an arrangement of vias;
a head-to-head structure between a via and a metal line in a via layer;
a head-to-head structure between vias in the via layer;
a via array structure; and
a weak point pattern.

In some cases, the via array includes N×N rectangular vias, 3×3 rectangular vias, 5×5 rectangular vias, and 1×N rectangular vias, where N is an integer greater than 5.

In some cases, the via array includes rectangular vias including square vias.

In some cases, the OPC patterns include patterns of a minimum critical dimension (CD) and a minimum pitch under a design rule.

In some cases, in step 2, each sample unit includes the OPC pattern, the corresponding value of the selected model parameter, and the corresponding wafer pattern data; and
the sample set is formed by aggregating all the sample units.

In some cases, prior to aggregating for forming the sample set in step 2, the method further includes performing a cleaning operation for removing all unsuitable sample units, the unsuitable sample units including:
the OPC pattern that fails to be properly exposed; and the wafer pattern with an ADI critical dimension measurement value less than the minimum critical dimension under a design rule.

In some cases, in step 3, the neural network includes a BP neural network.

In some cases, the BP neural network includes an input layer, more than one hidden layer, and an output layer.

In some cases, the selected model parameter includes an optical diameter.

In some cases, in step 4, a step of obtaining the optimal value of the selected model parameter includes:
obtaining a first curve of a simulation error varying with the values of the selected model parameter using the trained neural network; and
obtaining the optimal value of the selected model parameter based on a convergence trend of the first curve.

In the existing method, during OPC modeling, some model parameters such as the optical diameter process are not easy to select. If a large optical diameter is set, the OPC modeling involves a large amount of computation and long modeling time, and is low in efficiency. If a small optical diameter is set, the precision of the OPC modeling is reduced. In the present disclosure, a plurality of OPC patterns are preset according to a setting requirement of a lithography process layer layout, then an actual wafer pattern is obtained using the OPC patterns, the post-measurement wafer pattern, the OPC patterns, and the corresponding selected model parameter together form a sample unit and then form a sample set, and the sample set is input to a neural network and trained to obtain a corresponding OPC model for the OPC modeling. In practical OPC modeling, the OPC model obtained by training may be used to select a value of the corresponding selected model parameter and to perform OPC modeling, so that an optimal value of the selected model parameter may be quickly selected, and an OPC modeling speed as well as modeling precision may be improved.

### BRIEF DESCRIPTION OF THE DRAWINGS

The present disclosure is further described in detail below with reference to the accompanying drawings and specific embodiments:

FIG. 1 is a flowchart of a method for training an OPC modeling parameter according to an embodiment of the present disclosure;

FIGS. 2A-2D are example diagrams of four OPC patterns used in a method for training an OPC modeling parameter according to an embodiment of the present disclosure;

FIG. 3 is a structural diagram of a BP neural network used in a method for training an OPC modeling parameter according to an embodiment of the present disclosure;

FIG. 4 is a diagram illustrating a simulation error varying with values of an optical diameter when a selected model parameter is the optical diameter in a method for training an OPC modeling parameter according to an embodiment of the present disclosure;

FIG. 5A is a curve illustrating a line width varying with optical diameters that is measured using a first OPC pattern; and

FIG. 5B is a curve illustrating a line width varying with optical diameters that is measured using a second OPC pattern.

### DETAILED DESCRIPTION OF THE DISCLOSURE

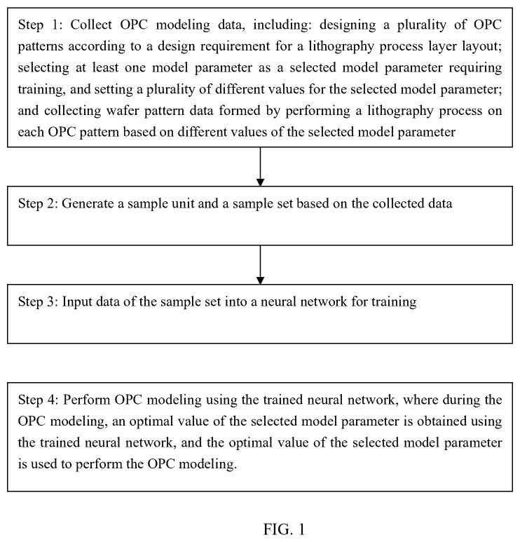

Referring to FIG. 1, which is a flowchart of a method for training an OPC modeling parameter according to an embodiment of the present disclosure, the method for training an OPC modeling parameter according to this embodiment of the present disclosure includes the following steps.
Step 1: Collect OPC modeling data, including:
designing a plurality of OPC patterns according to a design requirement for a lithography process layer layout;
selecting at least one model parameter as a selected model parameter requiring training, and setting a plurality of different values for each selected model parameter; and
collecting wafer pattern data formed by performing a lithography process on each OPC pattern based on different values of the selected model parameter;

In this embodiment of the present disclosure, the designed OPC patterns are required to cover all circuit layout pattern requirements in the lithography process layer layout.

The lithography process layer layout includes a hole layer layout. In other embodiments, the lithography process layer layout may also include other lithography process layer layout other than a via layer.

The designed OPC patterns are further described below by using following the hole layer layout as an example.

The OPC patterns corresponding to the hole layer layout include:

a grating formed by an arrangement of vias. In some embodiments, the vias include linearity holes or proximity holes varying with the gratings.

The OPC patterns further include: a head-to-head structure between a via and a metal line in a via layer;

a head-to-head structure between vias in the via layer; and a via array structure. In some embodiments, the via array includes N×N rectangular vias, 3×3 rectangular vias, 5×5 rectangular vias, and 1×N rectangular vias, where N is an integer greater than 5. A specific value of N is set according to a practical demand. The via array includes rectangular vias including square vias.

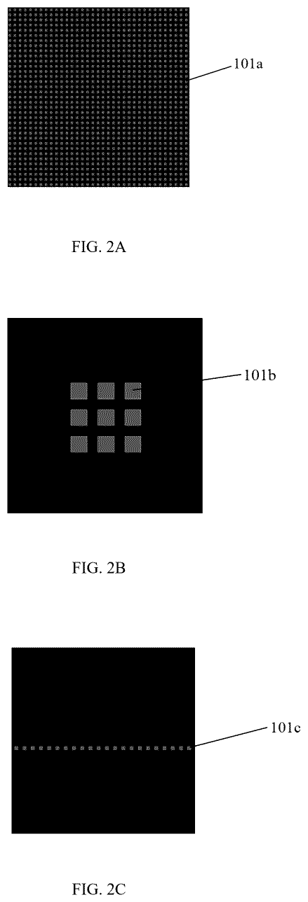

FIGS. 2A-2D are example diagrams of four OPC patterns used in a method for training an OPC modeling parameter according to an embodiment of the present disclosure.

FIG. 2A illustrates the N×N rectangular holes, with each via 101a in FIG. 2A being square.

FIG. 2B illustrates the 3×3 rectangular holes, with each via 101b in FIG. 2B being square.

FIG. 2C illustrates the 1×N rectangular holes, with each via 101c in FIG. 2C being square.

FIG. 2D illustrates the 1×N rectangular holes, with each via 101c in FIG. 2D being rectangular.

The OPC patterns further include a weak point pattern. The weak point patterns are patterns with poor process windows, and once the process fluctuates, the weak point patterns are prone to defects. The weak point patterns may appear in a static random access memory (SRAM) area and in a logical area.

The OPC patterns include patterns of a minimum critical dimension and a minimum pitch under a design rule.

More specifically, in this embodiment of the present disclosure, based on a corresponding specific hole layer of an actual product, in order to make an established OPC model have higher precision, different OPC patterns are designed according to a specific layout design requirement for the layer during the establishment of the OPC model, to cover circuit layout requirements in a real layout. A large amount of data collected include OPC patterns such as N×N square holes, 3×3 square holes, 5×5 square holes, and 1×N square holes, and OPC patterns such as N×N square holes, 3×3 square holes, 5×5 square holes, and 1×N square holes. Some specific weak points may also be collected according to different requirements, and added together to empirical data of the model. The patterns of the minimum CD and pitch under the design are also collected from the data. A sufficient amount of data is collected from these patterns to enable the OPC model to cover more distributions and to ensure the precision of the model.

In some embodiments, the selected model parameter includes an optical diameter.
Step 2: Generate a sample unit and a sample set based on the collected data.

In this embodiment of the present disclosure, each sample unit includes the OPC pattern, the corresponding value of the selected model parameter, and the corresponding wafer pattern data; and the sample set is formed by aggregating all the sample units.

In this embodiment of the present disclosure, prior to aggregating for forming the sample set, the method further includes performing a cleaning operation for removing all unsuitable sample units. In this way, the aggregated sample set does not include the unsuitable sample units.

In some embodiments, the unsuitable sample units include:
the OPC pattern that fails to be properly exposed; and
the wafer pattern with an ADI critical dimension measurement value less than the minimum critical dimension under a design rule.

That is, in this embodiment of the present disclosure, cleaning and aggregation operations are performed on the collected data, and cleared data includes the OPC pattern failing to be properly exposed, the pattern with an ADI value less than the minimum design CD, etc., and the collected data is aggregated to obtain required OPC model training data.
Step 3: Input data of the sample set into a neural network for training.

In this embodiment of the present disclosure, the neural network includes a BP neural network.

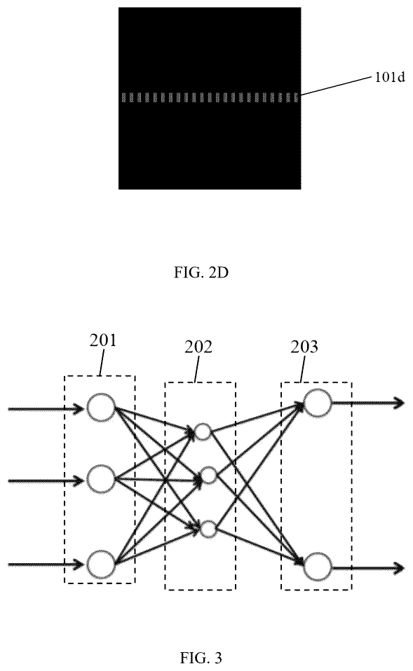

Referring to FIG. 3, which is a structural diagram of a BP neural network used in a method for training an OPC modeling parameter according to an embodiment of the present disclosure, the BP neural network includes an input layer 201, more than one hidden layer 202, and an output layer 203.

The training and learning process of the neural network includes the following steps.

The neural network is initialized, including:
initializing the number of nodes of the input layer 201, the hidden layer 202, and the output layer 203; and
initializing each weight in a weight matrix. Each weight is a weight coefficient of the impact of a node of a previous layer on a node of a next layer. For example, Wij denotes a weight of an i-th node, i.e., a neuron, of the input layer 201 on a j-th node of the hidden layer 202; and Wjk denotes a weight of the j-th node of the hidden layer 202 on a k-th node of the hidden layer 202.

A threshold of each layer is initialized. The threshold of each layer determines whether a neuron of the corresponding layer is activated. For example, when an input signal is greater than or equal to the threshold, the corresponding neuron is activated and produces an output; on the contrary, when the input signal is less than the threshold, the corresponding neurons is not inactivated.

Then outputs of the input layer 201, the hidden layer 202, and the output layer 203 are sequentially computed based on data of each sample unit inputted to the input layer 201. If a threshold of the input layer 201 is 0, an output of the input layer 201 is equal to an input, and in this case, only the outputs of each hidden layer 202 and the output layer 203 needs to be computed. These computations belong to a forward propagation process from input to output.

Subsequently, an error is calculated based on the output of the output layer 203 and the data provided by the sample unit; then the error is back-propagated, and during the back-propagation, each weight in the weight matrix is updated, and thresholds of all layers are updated sequentially.

After that, a loop iteration is performed to realize continuous variations of the weight and the threshold. After each loop, determining whether the iteration is ended is performed. If the iteration is not ended, the loop operation after initialization is repeated; and if a determining result is that the iteration is ended, the training and learning process is completed.
Step 4: Perform OPC modeling using the trained neural network, where during the OPC modeling, an optimal value of the selected model parameter is obtained using the trained neural network, and the optimal value of the selected model parameter is used to perform the OPC modeling.

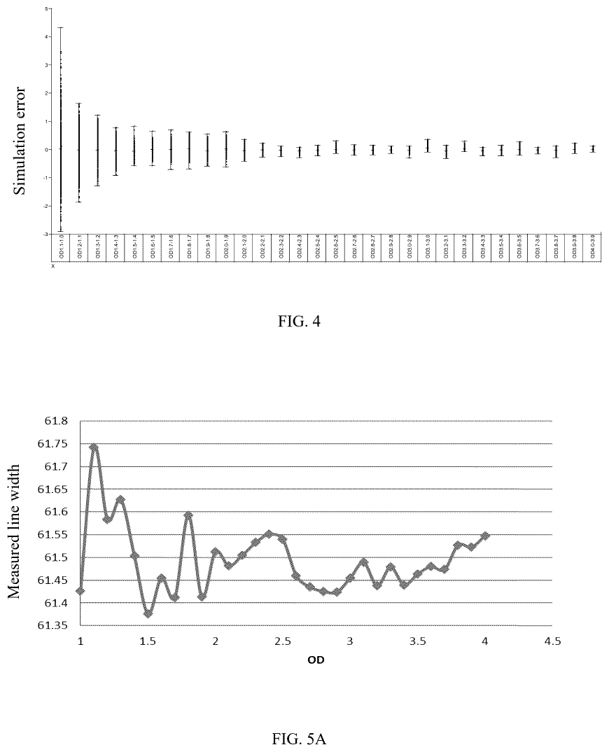

In this embodiment of the present disclosure, a step of obtaining the optimal value of the selected model parameter includes:
obtaining a first curve of a simulation error varying with the values of the selected model parameter using the trained neural network. Referring to FIG. 4, which is a diagram illustrating a simulation error varying with values of an optical diameter when a selected model parameter is the optical diameter in a method for training an OPC modeling parameter according to an embodiment of the present disclosure. In FIG. 4, the horizontal coordinate is the optical diameter, and the vertical coordinate is the simulation error.

After that, the optimal value of the selected model parameter is obtained based on a convergence trend of the first curve. It can be seen from FIG. 4 that simulation error data begins to present the convergence trend when the optical diameter is greater than 2.0. Therefore, the optimal value of the selected model parameter may be about 2.0, and the value corresponds to a sufficiently small simulation error, thus improving the modeling precision.

It can be seen from FIG. 4 that the data begins to present the convergence trend when the OD is greater than 2.0. In the following description, two key patterns are selected to validate their convergence, respectively.

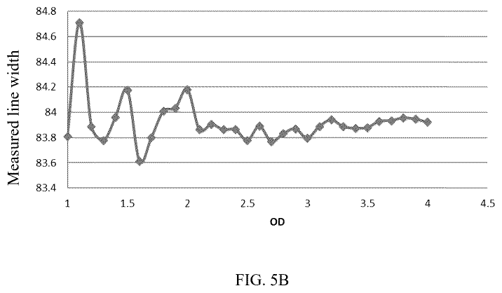

FIG. 5A is a curve illustrating a line width varying with optical diameters that is measured using a first OPC pattern. The first OPC pattern has a line width of 70 nm and a pitch of 99 nm. It can be seen from FIG. 5A that the curve in FIG. 5A presents a convergence trend when OD>2.0.

FIG. 5B is a curve illustrating a line width varying with optical diameters that is measured using a second OPC pattern. The second OPC pattern has a line width of 83 nm and a pitch of 120 nm. It can be seen from FIG. 5B that the curve in FIG. 5A presents a convergence trend when OD>2.0. The first OPC pattern and the second OPC pattern are both key patterns.

Therefore, corresponding OD values at the beginning of the convergence trend in FIGS. 5A and 5B are the same as the corresponding OD value at the beginning of the convergence trend according to FIG. 4 in this embodiment of the present disclosure. Accordingly, the actual measurement data corresponding to FIGS. 5A and 5B may effectively verify the optimal value of the selected model parameter obtained by the method of this embodiment of the present disclosure, with a normal verification result. Through the verification shown in FIGS. 5A and 5B, it may be found that the two key patterns each present a convergence trend when OD>2.0, with a small data error. Therefore, the OD determining method provided in this embodiment of the present disclosure is effective.

In the existing method, during OPC modeling, some model parameters such as the optical diameter process are not easy to select. If a large optical diameter is set, the OPC modeling involves a large amount of computation and long modeling time, and is low in efficiency. If a small optical diameter is set, the precision of the OPC modeling is reduced. In this embodiment of the present disclosure, a plurality of OPC patterns are preset according to a setting requirement of a lithography process layer layout, then an actual wafer pattern is obtained using the OPC patterns, the post-measurement wafer pattern, the OPC patterns, and the corresponding selected model parameter together form a sample unit and then form a sample set, and the sample set is input to a neural network and trained to obtain a corresponding OPC model for the OPC modeling. In practical OPC modeling, the OPC model obtained by training may be used to select a value of the corresponding selected model parameter and to perform OPC modeling, so that an optimal value of the selected model parameter may be quickly selected, and an OPC modeling speed as well as modeling precision may be improved.

This embodiment of the present disclosure provides a method for training an OPC modeling optical diameter based on a BP neural network. This method further increases a convergence speed of the OD by inputting collected OPC pattern data simulating an actual chip structure into the BP neural network for training and learning. By means the process method of this embodiment of the present disclosure, running time of the OPC model may be reduced, and the precision of the OPC model may be effectively ensured.

The present disclosure is described in detail above through specific embodiments, which, however, do not impose limitations to the present disclosure. Without departing from the principle of the present disclosure, a person skilled in the art may also made many other deformations and improvements, which should also be considered as the scope of protection of the present disclosure.

What is claimed is:

1. A method for training an OPC modeling parameter, comprising the following steps:
step 1: collecting OPC modeling data, comprising:
designing a plurality of OPC patterns according to a design requirement for a lithography process layer layout;
selecting at least one model parameter as a selected model parameter requiring training, and setting a plurality of different values for each selected model parameter; and
collecting wafer pattern data formed by performing a lithography process on each OPC pattern based on different values of the selected model parameter;
step 2: generating a sample unit and a sample set based on the collected data;
step 3: inputting data of the sample set into a neural network for training; and
step 4: performing OPC modeling using the trained neural network, wherein during the OPC modeling, an optimal value of the selected model parameter is obtained using the trained neural network, and the optimal value of the selected model parameter is used to perform the OPC modeling.

2. The method for training an OPC modeling parameter according to claim 1, wherein in step 1, the designed OPC patterns are required to cover all circuit layout pattern requirements in the lithography process layer layout.

3. The method for training an OPC modeling parameter according to claim 2, wherein the lithography process layer layout comprises a hole layer layout.

4. The method for training an OPC modeling parameter according to claim 3, wherein the OPC patterns corresponding to the hole layer layout comprise:
a grating formed by an arrangement of vias;
a head-to-head structure between a via and a metal line in a via layer;
a head-to-head structure between vias in the via layer;
a via array structure; and
a weak point pattern.

5. The method for training an OPC modeling parameter according to claim 4, wherein the via array comprises N×N rectangular vias, 3×3 rectangular vias, 5×5 rectangular vias, and 1×N rectangular vias, wherein N is an integer greater than 5.

6. The method for training an OPC modeling parameter according to claim 5, wherein the via array comprises rectangular vias comprising square vias.

7. The method for training an OPC modeling parameter according to claim 4, wherein the OPC patterns comprise patterns of a minimum critical dimension and a minimum pitch under a design rule.

8. The method for training an OPC modeling parameter according to claim 1, wherein in step 2, each sample unit comprises the OPC pattern, the corresponding value of the selected model parameter, and the corresponding wafer pattern data; and
the sample set is formed by aggregating all the sample units.

9. The method for training an OPC modeling parameter according to claim 8, prior to aggregating for forming the sample set in step 2, further comprising performing a cleaning operation for removing all unsuitable sample units, the unsuitable sample units comprising:
the OPC pattern that fails to be properly exposed; and
the wafer pattern with an ADI critical dimension measurement value less than the minimum critical dimension under a design rule.

10. The method for training an OPC modeling parameter according to claim 1, wherein in step 3, the neural network comprises a BP neural network.

11. The method for training an OPC modeling parameter according to claim 10, wherein the BP neural network comprises an input layer, more than one hidden layer, and an output layer.

12. The method for training an OPC modeling parameter according to claim 1, wherein the selected model parameter comprises an optical diameter.

13. The method for training an OPC modeling parameter according to claim 1, wherein in step 4, a step of obtaining the optimal value of the selected model parameter comprises:
obtaining a first curve of a simulation error varying with the values of the selected model parameter using the trained neural network; and
obtaining the optimal value of the selected model parameter based on a convergence trend of the first curve.
